(19) United States
(12) Patent Application Publication
(10) Pub. No.: US 2008/0310470 A1
(43) Pub. Date: Dec. 18, 2008

(54) Broadband semiconductor laser

(75) Inventors: Boon-Siew Ooi, Orefield, PA (US); Hery Susanto Djie, San Jose, CA (US)

Correspondence Address: RATNERPRESTIA, P O BOX 980, VALLEY FORGE, PA, 19482-0980, US

(73) Assignee: Lehigh University

(21) Appl. No.: 11/820,061

(22) Filed: Jun. 18, 2007

(51) Int. Cl. H01S 5/00; H01L 21/00

(52) U.S. Cl. 372/44.01; 438/46; 257/E21.002

(57) ABSTRACT

A broadband laser having a first cladding layer, a second cladding layer. A semiconductor structure between the first and second cladding layers has a layer of inhomogeneous quantum nano heterostructures. The inhomogeneous quantum nano heterostructures are engineered to lase at a ground state and at an excited state.

### FIELD

The present invention relates to optical emitters and, more particularly, to broadband semiconductor lasers.

### BACKGROUND

Broadband light sources can generally be obtained from several sources. Such sources include incandescent/halogen light sources; optically pumped crystal lasers, such as Ar-ion pumped Ti:Al₂O₃ lasers; optically pumped fiber based amplified spontaneous emission (ASE) sources; and, semiconductor light emitters.

Semiconductor light emitters are particularly attractive for many practical imaging and sensor system applications due to their compactness and relatively low energy requirement in comparison to other sources. The widely used semiconductor broadband light sources (or emitters) can be categorized into the light-emitting diodes (LEDs) and the superluminescent diodes (SLEDs). These semiconductor emitters exhibit a drawback of having low energy efficiency that typically produces up to few mWs (milli Watts) output power. Techniques have been developed to increase the power of such emitters but they are often impractical. For example, the power level of an SLED may be increased by integrating a semiconductor amplifier and a precise optical coating, however, at the expense of having a complex electrical injection scheme and a substantial increase in device geometry.

In contrast, a heterostructure laser diode (LD) can provide very high quantum efficiency and electric-to-optical power conversion. Due to limitations in the active material growth technology and the fundamental physics, however, conventional bulk heterostructure and quantum-well (QW) based laser diodes generally produce narrow spectrum emissions. For example, the spectrum missions can have a spectral width in the order of sub-nanometer for a single-mode laser, to a few nanometers for gain-guided multi-longitudinal mode lasers.

A multi-stage quantum cascade laser (QCL) can be engineered, based on the asymmetric intersub-band transition, to provide a radiative transition covering a wide wavelength spectrum as described in U.S. Pat. No. 7,010,010 issued to Capasso et al. This intersub-band broadband laser operates effectively under cryogenic temperatures while having a dramatic reduction in the laser line width and extremely low wall-plug efficiency at room temperature operation. This device does not realize a highly efficient, practical ultra-broadband laser, especially for a wavelength emission at the near-infrared (IR) region of ˜1000 nm-2000 nm. The realization of near-IR broadband laser using QCL approach may be unpractical due to the unavailability of suitable semiconductor material systems.

Simultaneous two-state lasing from the ground state (GS) and excited state (ES) has been observed from InAs/GaAs quantum-dot (QD) based interband semiconductor lasers. The wavelength emissions from such lasers, however, are well-separated such that the spectral region between such emission falls to zero. This result is similar to that achieved by a multi-wavelength laser array or a multi-longitudinal laser fabricated using state-of-art semiconductor laser technology.

### SUMMARY

In one aspect, the invention comprises a broadband laser having a first cladding layer and a second cladding layer. A semiconductor structure between the first and second cladding layers has a layer of inhomogeneous quantum nano heterostructures. The inhomogeneous quantum nano heterostructures are engineered to lase at a ground state and at an excited state.

In another aspect, the invention comprises a photonic device with a semiconductor structure having a layer of inhomogeneous quantum nano heterostructures. The inhomogeneous quantum nano heterostructures are engineered to lase at a ground state and at an excited state.

In another aspect, the invention comprises an optical coherent tomography system having a photonic device. The photonic device has a semiconductor structure for generating light. The semiconductor structure has a layer of inhomogeneous quantum nano heterostructures engineered to lase at a ground state and at an excited state. A wavelength splitter directs the light generated by the semiconductor structure to a sample and a photodetector detects an image from the sample.

In yet another aspect, the invention comprises a method of forming a broadband laser. A first cladding layer is formed on a substrate. An active region is formed on the first cladding layer with the active region having a plurality of inhomogeneous quantum nano heterostructures engineered to lase at a ground state and at an excited state. A second cladding layer is formed on the active layer.

### BRIEF DESCRIPTION OF THE DRAWINGS

FIGS. 1A-C are graphs illustrating a method for achieving a wide wavelength coverage according to an exemplary embodiment of the invention;

FIGS. 2A-B show a partial cross-section transmission electron microscopy (TEM) micrograph, and a partial schematic cross-sectional view, respectively, of an ultra-broadband laser device according to an exemplary embodiment of the invention;

FIGS. 3A-C illustrate methods for enhancing the inhomogeneity of QDs according to exemplary embodiments of the invention;

FIGS. 4A-C illustrate a layer intermixing process and the results thereof according to an exemplary embodiment of the invention;

FIG. 5A is a perspective view of an ultra-broadband laser according to an exemplary embodiment of the invention;

FIG. 5B is a plot of the gain characteristics of the laser shown in FIG. 5A;

FIGS. 6A-D are top-views of broadband lasers illustrating integrated resonator configurations according to exemplary embodiments of the invention;

FIG. 7A is a perspective view of an ultra-broadband laser according to an exemplary embodiment of the invention;

FIG. 7B is a plot of the gain characteristics of the laser shown in FIG. 7A;

FIGS. 8A-B illustrate series of broadband lasers integrated laterally and longitudinally, respectively, according to exemplary embodiments of the invention;

FIGS. 8C-E are plots illustrating the tailoring of the bandgap of the series of broadband lasers in FIGS. 8A-B according to an exemplary embodiment of the invention;

FIGS. 9 A-B illustrate a continuously tunable laser and a laser array, respectively, according to exemplary embodiments of the invention;

FIG. 10 illustrates a schematic diagram of a Fourier-domain OCT system having a broadband laser according to an exemplary embodiment of the invention;

FIG. 11 shows a flow chart of a method of manufacturing a broadband laser according to an exemplary embodiment of the invention;

FIG. 12 shows the photoluminescence (PL) signals at room temperature (RT) for exemplary QD materials according to an exemplary embodiments of the invention;

FIG. 13 shows the PL spectra at 77 K of a broadband laser according to an exemplary embodiment of the invention;

FIG. 14 shows plots from the broadband laser spectra measured at varying cavity lengths according to exemplary embodiments of the invention;

FIG. 15A shows plots from the broadband laser spectra at different current densities according to exemplary embodiments of the invention; and

FIG. 15B shows plots of the laser full-width-at-half-maximum (FWHM) and the spectrum ripple of a broadband laser according to an exemplary embodiment of the invention.

### DETAILED DESCRIPTION

A semiconductor light source having broadband characteristics with high power and high quantum efficiency may have many applications. Such applications include, for example, optical fiber telecommunications, fiber gyroscopes, optical time domain reflectometry, optical sensors, low coherence interferometers, high-resolution optical spectroscopy, and bioimaging systems through optical coherent tomography (OCT).

With regard to OCT, the sensitivity, signal quality, and the axial spatial resolution of current bio-imaging and probing systems using OCT technology are limited by the power and the bandwidth of their broadband light source. The capability of OCT systems integrated with endoscopes can be extended for various medical applications because water and hemoglobin exhibit little light absorption at near infrared wavelength, thereby allowing deeper light penetration into living tissue with tomography imaging. Such applications may benefit from high power and broad bandwidth light sources that enable improved data signals and increased axial resolution of OCT systems. It would be beneficial to have an efficient broadband semiconductor laser having a spectrally-flat wide wavelength coverage, high optical power, and that can operate at room temperature in a continuous wave mode.

According to an exemplary embodiment of the invention, an ultra-bright broadband light emitter comprises a semiconductor heterostructure laser including a p-i-n junction, one or more resonant cavities, and an optical waveguide. The heterostructure laser includes a plurality of inhomogeneous quantum-dots grown by the self-organization method and/or by engineering the material bandgap (e.g., by Q-well intermixing). This results in the synchronization of excited state lasing from the interband transitions to produce a wideband, nearly flat top spectrum, coupled Fabry-Perot oscillation in the device cavity. The material composition and thickness, growth parameter, postgrowth engineering and device geometry are tailored by using, for example, state-of-art molecular beam epitaxy or metal-organic chemical vapor deposition techniques, to ensure a broadened emission spectral linewidth at a high optical power, an adequate side-mode-suppression-ratio, low ripple, and continuous-wave room temperature operation. This results in a continuously tunable ultra-broadband laser source having high power that, depending on the wafer and device structure designs, can be used as a swept source in a frequency-domain optical coherent tomography system, for example. In an exemplary embodiment, the laser source has an output power ranging from a few tens of mW to a few watts.

According to another exemplary embodiment of the invention, a method is provided for making a broadband high power light emitter. The emitter includes a semiconductor heterostructure forming a p-i-n junction with a contact means for biasing the junction to generate light emission including the stimulated emission from the active region. The semiconductor heterostructure in the active region comprises a plurality of radiative interband transition regions formed by quantum confined nanostructures and a plurality of growth engineered surrounding layers. Such regions include wells or barriers at different materials or thicknesses or a plurality of spatial postgrowth engineered bandgaps where the energy transition and energy spacing are engineered to overlap and to provide a broadband emission.

Vertical engineering of epitaxial layers, by growth manipulation across a quantum confined semiconductor and by spatial engineering of material bandgap energy by postgrowth bandgap tuning, permits the formation of an overlapping lasing emission from confined states simultaneously. This may be achieved if the inhomogeneous broadening in the QD active region r is equal to or larger than the quantized energy separation ΔE. At a certain cavity length L and injection level J, the laser will emit the stimulated emissions simultaneously from available confined states—ground states (GS) and excited states (ES). The precise determination of device length may be obtained by precise cleaving means. Alternatively, spatially selective bandgap engineering (e.g., state-of-art quantum-well or quantum-dot/dash intermixing technology) may be used to form a transparent unpumped region to facilitate the cleaving uncertainties.

Another exemplary embodiment of the invention provides a method of producing a broadband laser with varying device geometries having an integrated mirror or a resonator to serve as an optical isolator for forming a resonant optical cavity. The integrated resonator enables the incorporation of other broadband lasers or other functional devices monolithically across a single chip. In an exemplary embodiment, multiple cavities are disposed side-by-side to provide the flexibility to perform gain equalization to each quantized state. This permits the laser bandwidth to be tuned by controlling the injection level to each electrode with dissimilar cavity lengths.

According to an exemplary embodiment of the invention, several broadband lasers with slightly different center wavelength emissions spatially may be integrated with a wavelength combiner to form an ultra-broadband laser source. The wavelength emission is tuned by spatially controlled intermixing, interdiffusion or layer disordering methods such that different areas of the wafer have different degrees of intermixing and thus different energy levels during operation. If the emission wavelength center is identical for each broadband laser, the integration will multiply the optical power output of such laser without scarifying the single mode emission in the lateral and transverse directions.

In an exemplary embodiment, a continuously wavelength tunable laser and a multi-wavelength laser array can be constructed from an ultra broadband laser by using a tunable filter or a wavelength demultiplexer, respectively. In another exemplary embodiment, the wavelength tunable array may be further assembled with other components to construct a frequency-domain optical coherent tomography (OCT) system having a high data acquisition speed and a high axial resolution.

Exemplary embodiments of the invention will now be described with reference to the figures. It will be appreciated that the spirit and scope of the invention is not limited to the embodiments selected for illustration. Also, it should be noted that the drawings are not rendered to any particular scale or proportion. It is contemplated that any of the configurations and materials described hereafter can be modified within the scope of this invention.

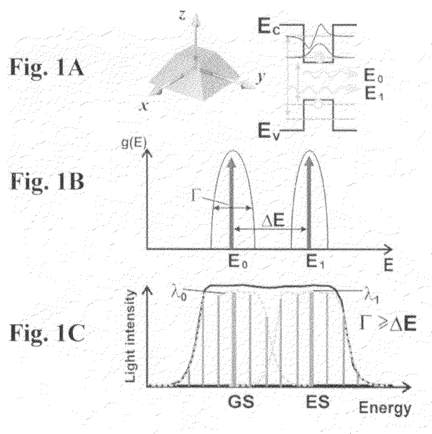

Embodiments of the invention disclose a new method for the fabrication of ultrabroad bandwidth, low ripple, high power semiconductor emitters. In exemplary embodiments, a spectrum width may span over tens of meVs under continuous wave and room temperature operations by either precisely controlling the device geometries and injection level and/or by employing a multi-electrode pumping scheme, to simultaneously excite the stimulated emission from quantized states in the QD structure as illustrated in FIG. 1A. Specifically, FIGS. 1B-C are plots illustrating the method to achieve the wide wavelength coverage exploiting the inhomogeneous broadening interband transition r in the quantum confined nanostructure and the simultaneous emission transition from confined states, the ground state (GS) and the excited state (ES). The broad lasing is achieved when the quantized energy separation ΔE is equal to or greater than Γ.

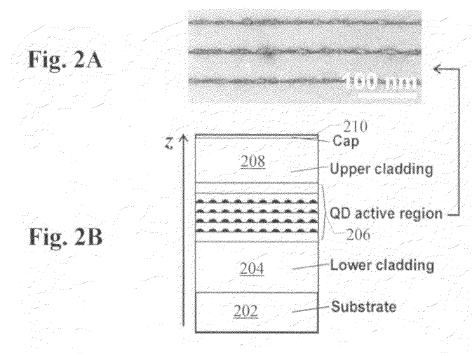

A semiconductor device according to an exemplary embodiment of the invention is described below that provides an edge emitting laser that produces wideband emission at high quantum efficiency and has a bandwidth that can be electrically tuned or widened by integrating several wideband semiconductor devices. There is shown in FIG. 2A a cross-section transmission electron microscopy (TEM) micrograph and in FIG. 2B a schematic cross-sectional view of an exemplary ultra-broadband laser structure according to an embodiment of the invention. Specifically, FIGS. 2A-B show cross sectional views of the semiconductor epilayers grown on a semiconductor substrate to form a transverse confinement for emitting photons. As illustrated in FIG. 2B, the wafer structure for the emitter includes a substrate 202, a first cladding layer 204, a highly inhomogeneous QD active region 206, a second cladding layer 208, and a cap or contact layer 210.

The active region 206 of the light source uses quantum confined nanostructures, comprising quantum-dots and/or dashes (QD) within a semiconductor matrix (barrier and cap layers). The plurality of QDs are within thin quantum heterostructure layers, such as QDs embedded in quantum-wells (QW) and barrier layers, and are used to emit photons from an edge, or facet, of a semiconductor die. The QD structure may be a three-dimensional or quasi-three-dimensional nanostructure of a first semiconductor material that has a bandgap energy and a refractive index. The matrix layers may be formed from layers of a second semiconductor material that has a higher bandgap energy and a lower refractive index than the first semiconductor material. The QWs and barriers may be formed from third semiconductor materials that have bandgap energies and refractive indices intermediate between the bandgap energy and the reflective index of the first and the second semiconductor materials, respectively. These semiconductor materials are used to assemble the active region 206 of the semiconductor emitting device where one or multi-stack QD layers are engineered by proper growth control so that different QDs are optically isolated and have different energy transitions and overlapping energy spacings to form a broadband emission.

The active core waveguide that may be current driven (e.g., injection of positively charge carriers) to provide optical gain in the active region 206 may be in the form of confined heterostructures. Such confined heterostructures may include but are not limited to separate confinement heterostructures (SCH), step-index SCH, and/or graded-index SCH, sandwiched between the first and second cladding layers 204, 208 and having a higher bandgap energy and lower refractive index than the average bandgap energy and average refractive index, respectively, of the confined heterostructure layers. The active waveguides may be gain-guided, rib, ridge or buried heterostructure waveguides preferably with the common mode cavity configurations including standard optical waveguide (SOW), large optical cavity (LOC), anti-resonant reflective optical waveguides (ARROW), wide optical waveguides (WOW), or the like.

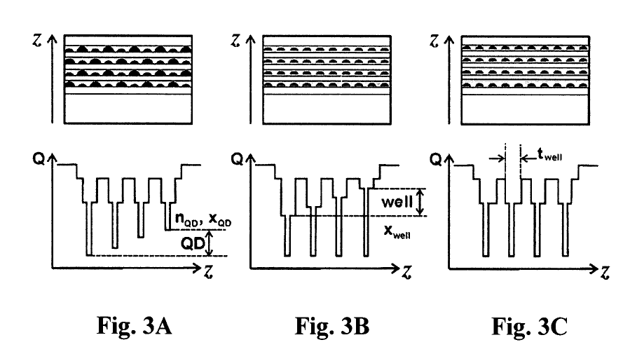

Exemplary methods for enhancing the inhomogeneity of QDs by staggering multi-stack QD layers with different epilayer properties in the active region across the growth direction, z, are described below with reference to FIGS. 3 A-C. FIG. 3a illustrates variations in QD properties such as the number of growth monolayers (n_{QD}) and the QD composition (x_{QD}). FIG. 3B illustrates variations in the composition of surrounding QW or barrier/capping layers (x_{well}). FIG. 3C shows variations in the thickness of surrounding QW or barrier/capping layers (t_{well}).

As shown in FIGS. 3 A-C, the inhomogeneous QD active region may include a plurality of QD layers. Each layer may include a plurality of QD sizes and compositions (x_{QD}), that are sandwiched within at least two adjacent layers including, but not limited to, quantum-wells, capping layers, barriers or matrix layers. The composition (x_{well}), thickness (t_{well}), and/or the amount of strain from adjacent layers may be altered as a function of the deposition condition which may be adjusted using factors such as growth temperature, pressure, growth pause, gas flow rate, and growth rate.

A plurality of QDs of different sizes and composition may be obtained by controlling the number of QD monolayers (n_{QD}), and thus the effective QD thickness, and/or by varying the QD composition. The QD monolayers may be formed, for example, using state-of-the-art self-assembled growth methods, including the Stranski-Krastanov (SK) growth mode, Volmer-Weber (VW) growth mode, migration-enhanced epitaxy (MEE) growth mode, cycled monolayer deposition (CMD) growth mode (sometimes referred as atomic layer epitaxy (ALE)), and droplet epitaxy, to form a device having a plurality of radiative photon emissions upon carrier injection that operates as a broadband laser with the simultaneous excitation of confined states. This may be achieved if the inhomogeneous broadening in the QD active region r is equal to or greater than the quantized energy separation ΔE. At a certain cavity length L and an injection level J, the laser will emit the stimulated emissions simultaneously from available confined states—ground states (GS) and excited states (ES).

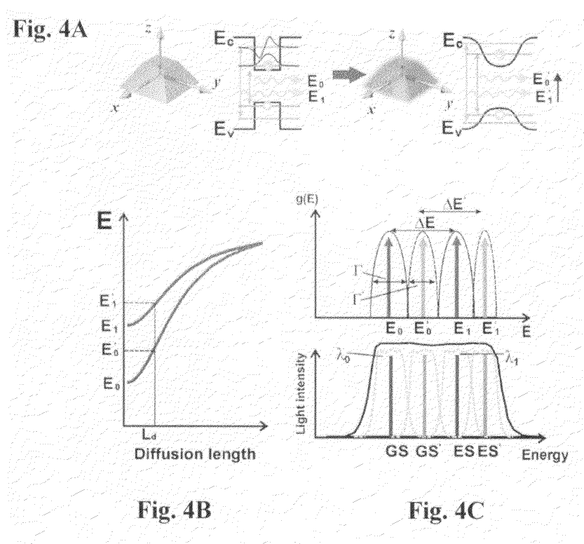

The availability of material and fundamental physics may limit the ability to grow a large QD dispersion and the wavelength emission dispersion. In an exemplary embodiment of the invention, as illustrated in FIGS. 4A-C, the QD dispersion may be enhanced spatially by modifying the material bandgap energy to flatten the intensity across the output spectrum from quantized states (GS and ES). FIG. 4A diagrammatically illustrates the layer intermixing process to spatially alter the material bandgap energy via an interdiffusion process. The process results in a widened bandgap energy E′, a smaller energy separation ΔE′, and a reduced inhomogeneous broadening value. The material bandgap can be tailored in a reproducible manner accordingly to form a device having a wavelength emission that is continuous with respect to diffusion length L_{d} in each different region along the laser cavity as illustrated in FIGS. 4B-C. Layer intermixing may be utilized if the energy separation between excited states in QD is larger than the inhomogeneous broadening.

The staggering of QD layers with a plurality of dot dimension and surrounding layers may result in a structure having a non-uniform carrier distribution upon carrier injection. The lateral transition energy created using intermixing technology helps to overcome photon reabsorption that overcomes the drawback of non-uniform carrier distribution. The bandgap may be modified by techniques such as the growth-and-regrowth technique and/or layer intermixing or disordering or interdiffusion techniques. The disordered or intermixed area will have a larger interdiffusion rate and therefore larger bandgap energy to achieve a criteria of E₀>>E₀′.

The lattice interdiffusion, or intermixing, or disordering processes are based upon the premise that a quantum heterostructure is inherently a meta-stable system due to the large concentration gradient of atomic species across the thin quantum layer and barrier interface. The process involves the introduction of beneficial defects to the material, such as ion implantation as described in U.S. Pat. No. 6,878,562 (issued Apr. 12, 2005 to Ooi et al.), which is incorporated herein by reference. During thermal annealing, the introduced impurities or created point defects alter the Fermi level and the high temperature enhances the solubility of certain point defects, thereby increasing the atomic interdiffusion rate which promotes intermixing. This results in an increased bandgap energy when the energy profile changes from being abrupt with transition energies E₀ and E₁ to being graded with QW bandgap profiles having transition energies E₀′ and E₁′ for GS and ES, respectively. The electronic states can be controlled by the degree of intermixing (i.e., by controlling the diffusion length L_{d} of the elemental species in the active region) as shown in FIG. 4B to flatten the intensity profile of light emission from multi-quantized state lasing as shown in FIG. 4C.

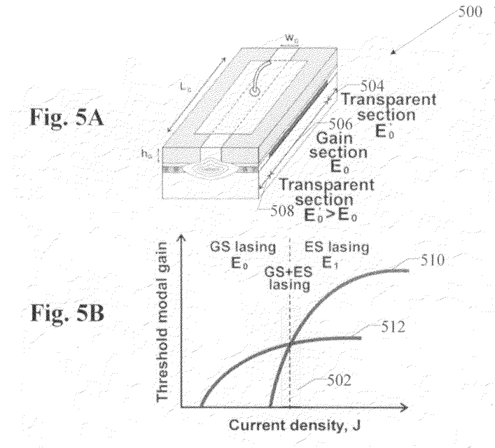

FIG. 5A illustrates a perspective view of single cavity configuration of an ultra-broadband laser 500 according to an exemplary embodiment of the invention. The laser 500 has an active cavity length L_{G} that is defined by using high precision cleaving or by incorporating a transparent window region. The transparent area may be formed with a larger bandgap material to minimize optical cavity loss using bandgap engineering utilizing growth-and-regrowth, selective area growth or spatially selective layer intermixing. At a certain cavity length L and current density I, the threshold modal gain for GS lasing and for ES lasing are comparable, thereby allowing the synchronous lasing states from GS and ES to construct a broadband emission. Although illustrated in FIG. 5A as a “ridge” structure waveguide having a height h_{G}, length L_{G}, and width W_{G}, FIG. 5A illustrates an exemplary embodiment and other cavity dimensions and geometries are within the scope of the invention.

FIG. 5B is a plot of the ES gain curve 510 and the GS gain curve 512 corresponding to the device shown in FIG. 5A showing net modal gain dependence to the injected current density 3 in the active region, where the gain is closely related to the electronic structure of the confined nanostructure. The gain saturates rapidly at a certain level with increasing current density, indicating that a finite number of confined states can be involved in the lasing. At a certain level of current injection, simultaneous state lasing is possible if the maximum gain achievable in ES is comparable to that in GS. Above this condition, the excited state lasing is achieved. To satisfy the both GS and ES state lasing, the cavity length L associated with the mirror loss αₘ in the laser cavity and the level of pumping current are two parameters that can be selected to determine the state emission. If the energy splitting ΔE between GS and ES is equal or less than the inhomogeneous broadening in QD stacks r the state lasing will produce a broad, continuous lasing spectrum.

In an exemplary embodiment of the invention, precise determination of device cavity length is desirable and the level injection is desirably localized in the region to satisfy the synchronous state lasing condition. Thus, a wide bandwidth may be obtained at a moderate current density range as shown in the grayed region 502 in FIG. 5B. According to another exemplary embodiment of the invention, this bandgap engineering process can also be introduced during fabrication to form a highly transparent, unpumped window section, in addition to the conventional cleaving process. The transparent region with a bandgap energy E₀′ can be formed by the bandgap engineering methodologies described above, including layer intermixing methods, such that the selected area in the wafer will have a larger bandgap energy resulting in a negligible propagation loss at the wavelength operation in comparison to the laser having a smaller bandgap energy area. In an exemplary embodiment of the invention, the bandgap shift between the gain 506 and transparent sections 504, 508 is greater than 60 meV. The incorporation of the window section increases the ability to tolerate fabrication tolerances of the laser cleaving process without affecting the overall laser performance significantly. Using this technique, the length of the active gain section is accurately defined by lithography instead of cleaving.

While exemplary methods of forming a broadband tunable laser are described above, exemplary embodiments of the invention encompass the monolithic integration of such a broadband laser to other similar devices to form a bandwidth tunable laser, a laser array or other functional photonic devices. Exemplary embodiments of the invention encompass methods for integrating a broadband laser according to an embodiment of the invention with one or more photonic devices on the same semiconductor substrate. Such a device may be constructed by forming an optical resonator that isolates the Fabry-Perot (FP) oscillation to ensure that the device can emit either each wavelength singly or their desired combinations.

Exemplary embodiments of the invention include the extension of a broadband laser device (BLD) according to an embodiment of the invention to form an ultra-broadband laser. Such an ultra-broadband laser may be formed, for example, by integrating monolithically several BLDs according to exemplary embodiments of the invention, where such BLDs operate at different center wavelengths. An ultra-broadband laser may serve as a light source to provide a continuously tunable laser source and multi-wavelength array. The latter, if applied in a frequency-domain optical coherent tomography (OCT) system, may provide micrometer scale axial resolution and increased data acquisition.

In another exemplary embodiment, the optical resonator can be incorporated in the device configuration, instead of the conventional cleaved facets, with a plurality of dielectric thin film coatings; hence, the Fabry-Perot (FP) oscillation may not rely solely on the reflectivity provided from the cleaved facets that limit the functionality of devices. The optical resonator acts as an optical isolator or wavelength selector to provide a resonant optical cavity that segregates and isolates interference from other surrounding devices. In an exemplary embodiment, the resonator back-couples the resonant frequency into the waveguide, thereby ensuring that in the integrated devices the broadband laser can emit either each lasing wavelength independently or in desired combinations. The reflectivity can be controlled by engineering the geometry of resonators such that the intended lasing wavelength lies within the reflectivity spectrum of resonator. The coupling strength can be improved by cascading several resonators in the of case ring or microdisk resonators. Since it is not necessary to have an electrical contact for the resonator, this approach may simplify device fabrication and operation.

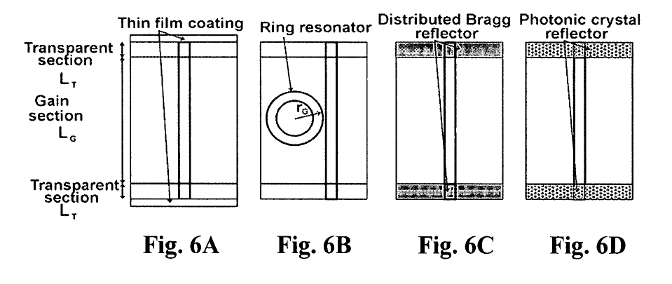

FIGS. 6A-D depict top-views of exemplary broadband lasers having conventional dielectric thin film coating or integrated resonator configurations to satisfy the lasing condition in the laser cavity. The resonator acts as optical isolator for a broadband laser to allow the on-chip integration of the broadband laser with other functional photonic devices including other broadband lasers, a semiconductor amplifier, an optical waveguide, a modulator, a photodiode, etc. The resonator section may be, for example, a total internal reflection (TIR) mirror, a ring or microdisk resonator, a distributed Bragg reflector (DBR) mirror, or a photonic crystal (PCX) and as illustrated in FIGS. 6 A-D, respectively. The passive section of resonators in the ring resonator, DBR, PCX, or TIR mirrors should be transparent to the operating wavelength of the laser with the energy bandgap E₀′ being larger than the bandgap energy of the gain medium E₀. Alternatively, the wavelength isolator can be constructed along the active gain section using a distributed feedback Bragg grating mirror, which may eliminate a step of making a certain section transparent.

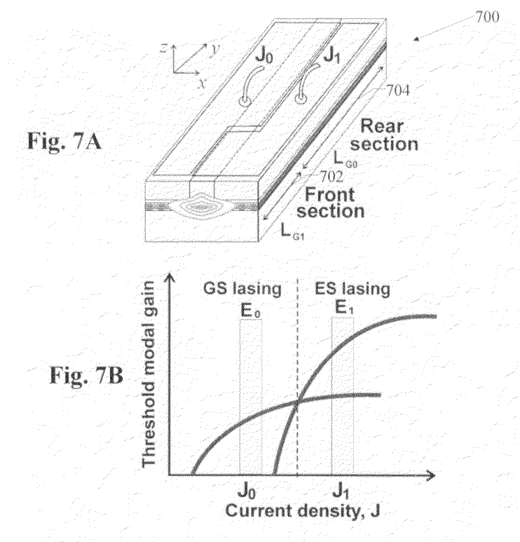

With the device 500 illustrated in FIG. 5, a high pumping current may possibly reduce the overall linewidth of the laser as the GS gain 512 begins to saturate, causing the lasing from the ES1 level to be dominant. This may result in a small range of broadband laser operation owing to the exponential dependence of output power on modal gain. According to another exemplary embodiment of the invention, multi-electrode schemes with broadband lasers having dissimilar cavity lengths of active regions, defined by an integrated optical resonator, can modulate the waveguide loss and control the total gain across the QD active medium. A multi-cavity design is illustrated by exemplary device 700 in FIG. 7A which allows for individual state lasing for each electrode at a more flexible current injection as shown in FIG. 7B.

Device 700 in FIG. 7A is a schematic of a spatially-integrated, electrically-tunable ultra-broadband device employing the multi-electrode scheme with dissimilar cavity lengths L_{G1} and L_{G0}. The cavity length can be determined by an integrated resonator that satisfies the threshold modal gain under certain current injection to excite either the GS or ES levels from front and rear. The cavity segmented method allows for flexible control of output power and of the bandwidth of the laser spectrum by independently controlling the current injection J₀ and J₁ to each individual gain section. Independent control over the excitation of various sections of an active region, each with a different wavelength coverage, permits the optical gain to be fully utilized at a wide range of possible wavelength coverage, selectable by electronic control in a fast manner. Although the exemplary device 700 is shown as having two electrodes in FIG. 7A, exemplary embodiments of the invention encompass devices having a greater number of independent electrodes to provide the gain equalization.

The exemplary device 700 illustrated in FIG. 7A and described above has two electrically independent electrodes, front and rear sections with cavity lengths of L_{G1} and L_{G0}, respectively. The front and rear sections are separated by an isolation region which has a high resistivity and is transparent. To achieve a lasing condition, the minimum gain desirably exceeds a total resonator loss from absorption and mirror losses. The front section 702 is designed to have a shorter cavity length with a larger mirror loss so the radiative transition is localized around excited state lasing with photon energy E₁ at a given current injection of J₁. If pumping of the rear section 704 is increased to excite only the ground state transition with photon energy E₀, excited photons will be amplified further by the front section. Because both pumping levels are above the transparency condition, this scheme permits the oscillation from both E₀ and E₁. Under certain ratios (i.e., J₁/J₀) of injected currents, the cavity accommodates photon oscillation for both states to form a broadband laser emission from inhomogeneous QDs. Therefore, the multi-electrode pumping scheme of device 700 allows effective control of laser power and bandwidth emission from a sum of two or more quantized state lasing. It also enables laser switching, and hence bandwidth tuning, from one state to another state by changing the current level applied to each section.

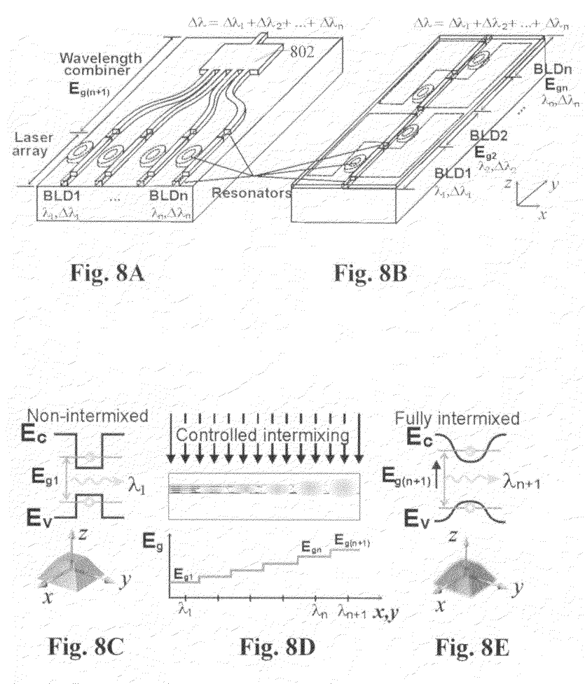

Broadband lasers according to embodiments of the invention may be integrated monolithically to form an ultra-broadband laser according to exemplary embodiments of the invention. A plurality of broadband lasers operating at a different center wavelengths and isolated by isolators or resonators, can be integrated monolithically to form an ultra-broadband laser without the interference of optical feedback between or among the lasers. Spatially parallel and serial broadband lasers, forming ultra-broadband lasers that realize low-cost high power broadband transmitters having a single fiber coupling, are schematically illustrated in FIGS. 8A-B, respectively. For parallel integration of multi-channel broadband lasers, an N device-waveguide coupler 802 (i.e., a wavelength multiplexer or combiner) couples each broadband laser to a single-mode fiber. The method is potentially cost-effective and exhibits a high scaling capability with increased bandwidth. The spatially controlled intermixing or disordering can be employed to tailor the bandgap energy E_{G} of each section in a simple and reproducible manner.

The bandgap of each broadband laser E_{g} (BLD1 to BLDn) in FIGS. 8A-B may be tailored using a one-step spatially controlled intermixing or disordering method as diagrammatically illustrated in FIGS. 8C-D. This results in the predicted change in GS transition energy (E₀) and first ES transition energy (E₁) simultaneously as a function of diffusion length as illustrated in FIG. 8E. Without the alteration of bandgap energy for each BLD device in the array, the array of broadband lasers BLD1 to BLDn has a multiplied output power in comparison to a single broadband laser while retaining a substantially single lateral mode of output beam profile to provide an efficient alignment of device output to the fiber.

Intermixing may be performed with multiple steps of fabrication or in a single stage process by controlling the number of defects reaching the semiconductor area, that in turn increase the degree of intermixing in the selected area upon thermal heating process. Methods of intermixing are described in U.S. Pat. No. 6,617,188 (issued Sep. 9, 2003 to Ooi et al.) which is hereby incorporated by reference. Defects may be introduced by intermixing methods such as, for example, impurity induced disordering and impurity-free induced disordering through impurity diffusion, ion implantation, laser irradiation, dielectric cap annealing, plasma exposure and low temperature grown III-V thin layer.

Each BLD is coupled to single output using a transparent waveguide that can be in the form of Y-junction coupler, a multi-branch coupler, or a multi-mode interference (MMI) coupler, for example. A multiplied output power can be achieved if identical BLDs are joined together with the wavelength combiner allowing the preservation of single lobed far field output beam profiles to ease the optical fiber coupling process as compared to coupling each laser individually to an optical fiber.

According to an exemplary embodiment of the invention, a BLD according to an embodiment of the invention is integrated with other functional devices monolithically. Such other device may include, for example, without limitation, a semiconductor optical amplifier, a photodiode, an optical modulator, and/or waveguides. The bandgap of the integrated BLD devices may be tuned accordingly using bandgap engineering methods as described above.

In addition to OCT applications, broadband laser(s) according to exemplary embodiments of the invention may be used to form multi-wavelength laser and continuously tunable laser sources for applications, for example, such as bimolecular imaging and sensing and wavelength division multiplexing (WDM) systems.

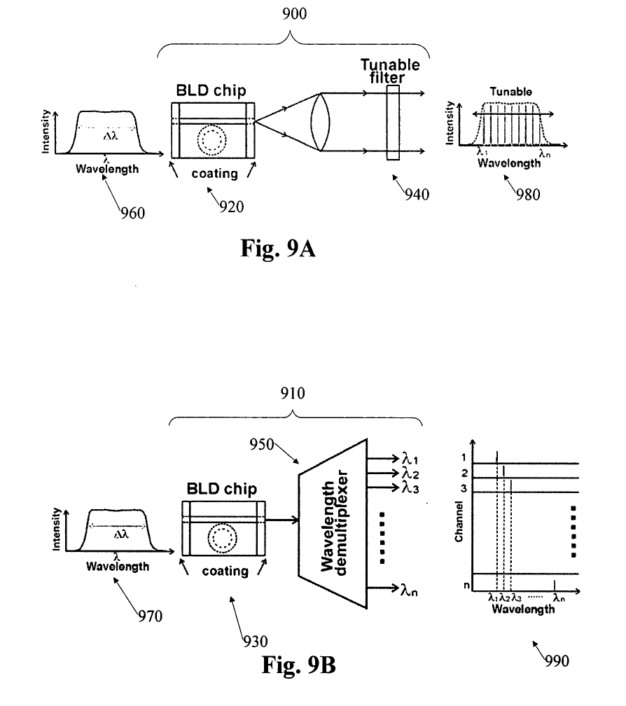

FIG. 9A illustrates a partial schematic diagram of a continuously tunable laser 900 including a broadband laser 920 as switched source according to an exemplary embodiment of the invention. The wavelength of the device 900 is tuned using a tunable filter 940 (i.e., a wavelength selector) which may be implemented, for example, by a Fabry-Perot tunable filter, a Fiber-Bragg grating, a diffraction grating, a micro-electromechanical (MEMs)-based filter, an acousto-optic filter, a magneto-optic filter, or a liquid crystal tunable filter. The emission of the laser 920 is illustrated by diagram 960 and the emission of the tunable laser 900 is illustrated by diagram 980. The broadband laser 920 is a broadband laser according to an exemplary embodiment of the invention as described above and may be implemented on a chip or compact package such as, for example, a 14 pin butterfly package. The continuous emission nature of the broadband laser 920, in combination with an appropriate wavelength selector, provides a truly tunable device 900. The device 900 exploits the FP modes in the laser 920 cavity that usually produces the quasi-continuous wavelength sweep.

FIG. 9B illustrates a partial schematic diagram of a laser array 910 including a broadband laser 930 as an arrayed source, according to an exemplary embodiment of the invention. The device 910 provides an array of discrete wavelength emissions by demultiplexing the wavelength emission of one or more broadband lasers 930. The wavelength emission from the laser array 910 is received by a wavelength demultiplexor 950 (or separator) which may be implemented, for example, by a multi-branch waveguide coupler, a Fiber-Bragg grating array, an arrayed waveguide grating (AWG), a diffractive grating, a holographic grating or an Echelle grating. The emission of the laser 930 is illustrated by diagram 970 and the emission of the laser array 910 is illustrated by diagram 990.

According to an exemplary embodiment of the invention, an ultrafast switched source is provided by routing or directing the output of the demultiplexor 950 to a wavelength multiplexer (not shown), where each channel of the multiplexer is integrated with electro-absorption (EA) optical switches to select the operating wavelength. Such a large-scale integrated device based on the broadband laser 930 may have a sub-microsecond or less switching time and may be applicable, for example, in packet-switched wavelength division multiplexing (WDM) networks.

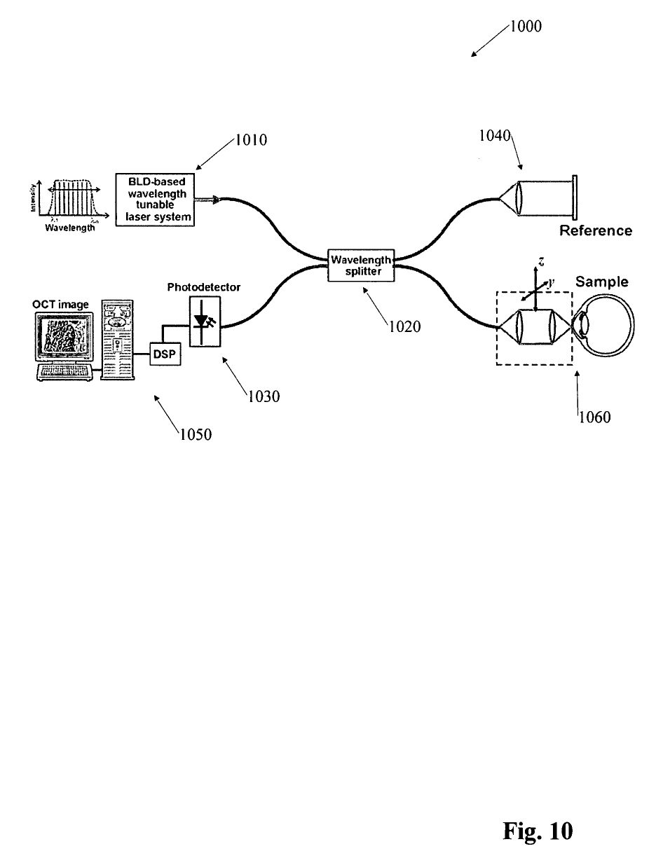

There is shown in FIG. 10 a schematic diagram of a Fourier-domain OCT (FDOCT) system 1000 according to an exemplary embodiment of the invention. The FDOCT system 1000 includes a wavelength tunable laser source 1010 (such as the exemplary tunable laser 910 shown in FIG. 9) that includes using an ultra-broadband laser according to an exemplary embodiment of the invention as a frequency-swept light source. The system 1000 further includes a wavelength splitter or beam splitter 1020, a photodetector 1030, a reference mirror 1040, and an image signal processor 1050 for imaging a sample 1060. In an exemplary embodiment, the laser source 1010 has a wavelength emission above 1 μm, thereby allowing the OCT system to use a higher incident power for tissue imaging. According to an exemplary embodiment, the system 1000 is used for ocular imaging. The higher incident power allows for the system 1000 to have deeper penetration, faster data acquisition, and improved sensitivity. Further, the use of the compact and efficient swept source 1010 according to an embodiment of the invention, as compared to use of a spectrometer and in-line camera in other FDOCT systems, provides a simpler system configuration, reduces system cost, and is allows for balanced detection.

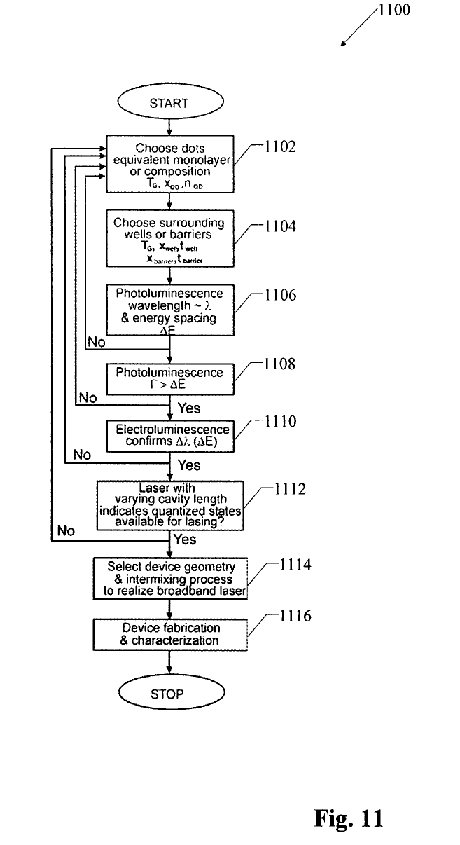

A method of manufacturing a broadband laser according to an exemplary embodiment of the invention is described below with reference to the flow chart 1100 in FIG. 11. The illustrated manufacturing method of a broadband laser includes an iterative process to achieve the highly inhomogeneous QD active region comprising one or more QD layers with predetermined energy spacing between GS and ES states without exceeding the critical thickness for introducing strain relaxation or dislocations. According to an exemplary embodiment of the invention, a semiconductor laser designed using this method may produce a QD laser having a highly inhomogeneous optical gain with precise peak wavelength control, and optimized bandwidth and lasing performance.

The design of the broadband laser begins by selecting the dimension (e.g., by controlling the number monolayers of QDs (n_{QD})), the composition of the QDs (x_{QD}) and the growth temperature (T_{G}) in step 1102. In step 1104, the thickness (t_{well} and t_{barrier}), composition (x_{well} and w_{barrier}) and the growth temperature (T_{G}) of the surrounding matrix, quantum wells and barriers are selected. The emission wavelength, the number of electronic states, and the refractive index of the gain material may be determined by the parameters identified above. The optimization of these three parameters may reduce the effective energy splitting ΔE between quantized states by increasing the dispersion of confined states from the QD assembly or by increasing the number of available confined states. In an exemplary embodiment of the invention, the energy splitting is 60 meV or less, and the exemplary energy spacing is between 25 and 50 meV, to facilitate the broad lasing emission from the inhomogeneously isolated QDs. The small energy separation in an exemplary embodiment is not less than the usual values of kT (k=Boltzmann's constant and T=the absolute temperature) to prevent having poor thermal characteristics of the broadband laser.

After the material growth in steps 1102 and 1104, photoluminescence (PL) measurement and/or other state-filling spectroscopies are performed on the wafer in step 1106 to determine the peak emission wavelength (λ), and the energy splitting (ΔE). Steps 1102 and 1104 are repeated until the PL signal matches the designed λ and ΔE. Power dependent photoluminescence is then performed in step 1108 to determine the energy spacing (Γ). For broadband emission, it is desired to obtained Γ>ΔE. Steps 1102, 1104 and 1106 are repeated until the wafer produces the desired r.

After step 1108, the epi-wafer is ready to be fabricated into an emitter for electroluminescence characterization in step 1110. The emitter may be fabricated using a state-or-art diode fabrication step. The characterization in step 1110 is required to further verify the ΔE through the measurement of Δλ of the amplified spontaneous emission (ASE) spectrum of the diode. Steps 1102, 1104, 1106, and 1108 are repeated until the wafer produces the desired performance.

Once the designed ΔE is confirmed, semiconductor lasers with varying cavity length will be fabricated in step 1112 to determine the optimum cavity that will support simultaneous lasing of multiple energy stages 1112. Steps 1102-1110 are repeated until the wafer produces the desired performance.

The optimum laser cavity that supports broadband lasing action may be determined in step 1112. A selective intermixing process may then be applied in step 1114 to control the effective active cavity to realize a broadband laser. The final step 1116 of the production of the broadband laser involves standard device fabrication using state-of-art technology and characterization techniques.

Several growth iterations with slightly dissimilar QD energy transitions may be employed to further improve the inhomogeneous broadening as shown above with reference to FIG. 8. The number of asymmetric QD stacks may be compromised to achieve broadband emission and an adequate laser performance. In an exemplary embodiment of the invention, layer intermixing is introduced spatially after the growth completion of laser structure to ensure the widely continuous coverage of emission intensity.

### EXAMPLES

The following non-limiting example describes a broadband semiconductor laser, according to an exemplary embodiment of the invention, based on inter-band transition designed for operation of the laser at a center wavelength of 1.1-1.2 μm. Various III-V compound semiconductor materials, growth parameters, device dimensions, fabrication procedures, and laser characterization conditions are provided by way of illustration only and, unless otherwise expressly stated, serve to illustrate exemplary embodiments of the invention and are not intended to limit the scope of the invention.

The QD laser structure is based on a typical p-i-n configuration grown on Si-doped, (100)-oriented GaAs substrate using a cycled monolayer deposition (CMD) growth mode of molecular beam epitaxy (MBE) as described by Djie et al., in J. Appl. Phys., Vol. 100, Art. No. 033527, 2006, which is hereby incorporated by reference. This approach permits fine control of dot size and the energy separation between quantized states in QDs. The undoped active region includes five InGaAs QD stacks and six 40 nm thick GaAs matrix layers to minimize the vertical coupling effect and strain interaction. Each dot layer is comprised of five pairs of alternating InAs and GaAs monolayers. Under a constant As flux, the growth is interrupted after each monolayer in order to stabilize the surface. This active region is sandwiched by two short-period superlattices of 20 pairs of 2-nm Al_{0.3}Ga_{0.7}As and 2-nm GaAs and two 1500-nm-thick Al_{0.3}Ga_{0.7}As cladding layers. A highly doped 200-nm GaAs contact layer is then grown to complete the laser structure. The bulk cladding, superlattice, and contact layers are all grown at (Al)GaAs substrate temperature of 600° C., while the QD active region is grown at 515° C. In comparison, conventional 1.3 μm QD structures have a relatively high homogeneity in a device where each QD layer is sandwiched within quantum-well (QWs) heterostructures grown using Stranski-Krastanov (SK) growth mode in MBE.

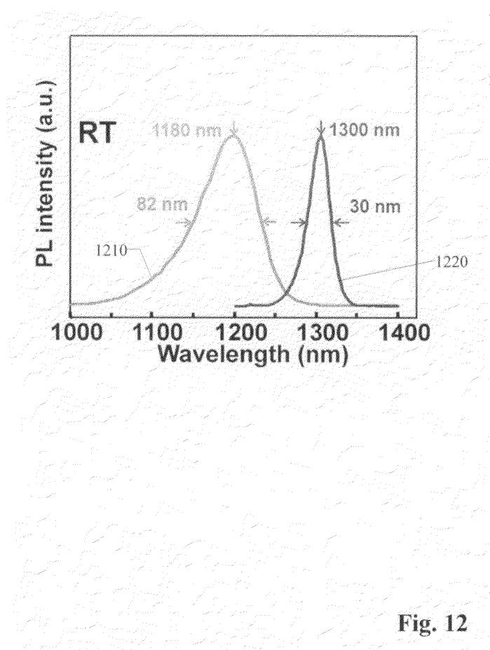

The photoluminescence (PL) signals at room temperature (RT) for exemplary QD materials according to exemplary embodiments of the invention are shown in FIG. 12. The plot 1210 corresponds to QD materials grown with highly dispersive InGaAs/GaAs QDs (i.e., CMD-type QDs). The plot 1220 corresponds to QD materials grown with low dispersive InAs/InGaAs QDs (i.e., SK-type QDs). No dislocation was observed from both QDs. The former provides a substantially greater PL line width than the latter at similar excitation power levels (e.g., 1500 W/cm2). Specifically, the size and compositional variation of the CMD-type QDs is about 2 times larger than SK-type QDs as designed.

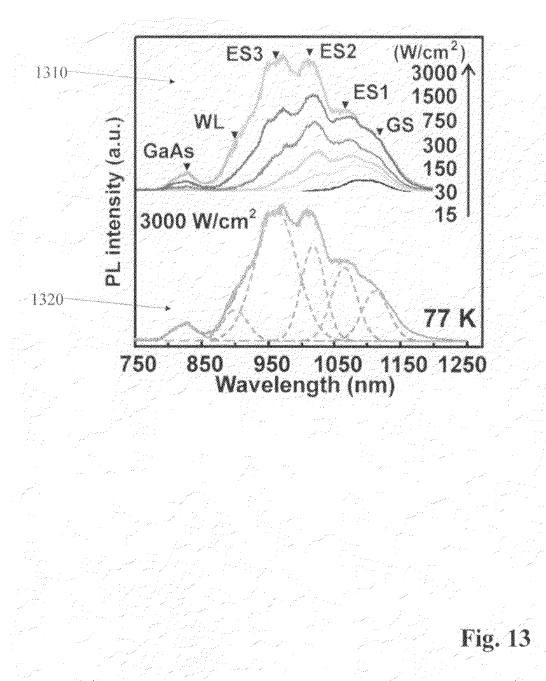

The PL analysis illustrated in FIG. 12 was performed using a 532 nm laser as an excitation source with an optical density of 1500 W/cm² on both structures at room temperature (RT). The PL spectra provide information related to the dot inhomogeneity from the radiative transition of GS level and are summarized in FIG. 12 for both QDs. Consistent with the TEM measurement, the PL linewidth of the CMD-type QDs is 82 nm (76 meV) as shown on plot 1210, which is significantly broader than the SK-type QDs of 30 nm (23 meV) as shown on plot 1220. The broad linewidth observed from the PL spectra originates from the simultaneous excitation of a relatively large dot assembly (e.g., ˜10⁶ dots, probed using a 62.5 μm diameter fiber) that have large variation in size and composition. The large size and composition dispersion of CMD-type QDs were observed and confirmed from the TEM measurements. In an exemplary embodiment of the invention, the variation of size among the QDs (or quantum nano heterostructures) is greater than ten percent (10%). This randomness results from the nucleation and formation of QDs with increased inhomogeneity in QD size and fluctuations in the size distribution, thereby realizing a broadband laser according to an exemplary embodiment of the invention. The quantized QD state transition may be examined using state-filling PL spectroscopy at 77 K with varying optical power density as described below with reference to the plots shown in FIG. 13.

FIG. 13 shows plots of the PL spectra at 77 K obtained with varying excitation power level from highly dispersive QDs. The triangles in plot 1310 represent the peak energy from the quantized states after the deconvolution of the PL spectra at an excitation density of 3000 W/cm² with the multi-Gaussian curves shown in plot 1320. The plots in FIG. 13 display resolved confined state PL peaks as the excitation intensity is raised up to 3000 W/cm² for the CMD-type QDs. At an excitation density below 15 W/cm², a single PL peak corresponding to the GS transition is observed. As the excitation power increases, the PL spectrum is gradually broadened, with ES peaks appearing towards the higher energy region. The ground state becomes saturated and the emission of the first excited state ES1 begins to dominate above 30 W/cm².

At an excitation density of 3000 W/cm², the exemplary PL spectrum includes up to six Gaussian fits representing emissions from GS, ES1 to ES3, wetting layer (WL), and the GaAs substrate. The sublevel energy separation is almost equal. The energy separation between GS and ES1 at 77 K is 46 nm (49 meV), which is considerably smaller when compared to the conventional InAs QD energy separation of >60 meV.

Broad area lasers with 50 μm wide oxide stripe lasers were fabricated from both the CMD-type and SK-type QD samples. The fabrication process involved the deposition of a 200 nm thick SiO₂ layer, the definition of 50 μm wide oxide windows by photolithography and wet etching, the evaporation of a p-type (Ti/Au) contact, substrate thinning, the evaporation of an n-type (Au/Ge/Au/Ni/Au) contact, and metal alloying in a rapid thermal processor at 360° C. for 1 minute. The lasers were cleaved into bars with different cavity lengths L and tested on a temperature controlled heatsink at 20° C. under pulsed operation (i.e., 1 μs pulse width and 0.1% duty cycle). The laser exhibited typical light-current (L-I) and current-voltage (I-V) characteristics with a “turn on” voltage of ˜1.2 V.

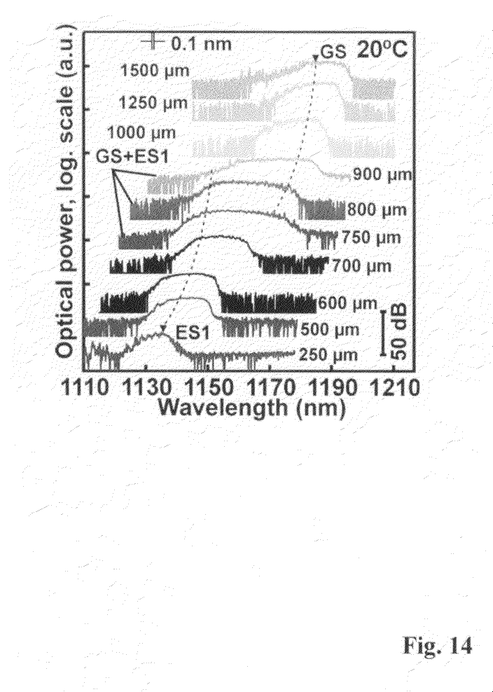

FIG. 14 shows plots of the laser emission from different cavity lengths at an injection level of 2×Iₜₕ. The spectrum resolution of the analyzer set to 0.1 nm. The lasing spectrum relies strongly on the device length. For a long cavity (e.g., L=1000 μm and longer), the carriers begin to fill the GS level, resulting in a peak emission wavelength at 1180 nm. At L=700 μm and shorter, the emission of the laser results from the ES1 level at 1132 nm. The different lasing states between GS and ES1 are comparable to the previous energy separation from the PL measurement. These lasers exhibit a lasing full-width-at-half-maximum (FWHM) of more than 10 nm from single quantized states, which is broader than the typical FWHM from the SK-type QDs of 4.5 nm (3.3 meV) from GS emission. As the CMD-type QDs are highly inhomogeneous, the broader linewidth is caused by the spectral hole burning of QDs leading to the localized nature of lasing states from the spatially and energetically isolated QDs.

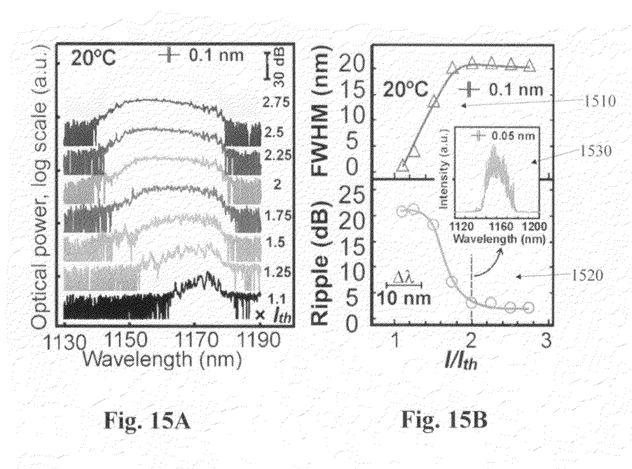

At the intermediate lengths (L=750, 800 and 900 μm), very broad emission spectra (>20 nm) are measured. This broad spectral width from the intermediate cavity length results from the simultaneous emission of two states (GS+ES1) lasing. The laser exhibits an overlapped state lasing and the intensity does not fall to zero in the spectral region between the state lasing because the energy separation between the GS and ES1 of the highly dispersed CMD-type QDs is relatively small, as evidenced from TEM and state-filling PL spectroscopy described above. The multi-longitudinal mode lasing from the FP oscillation can be well-resolved for conventional SK-type QD lasers with a spectral resolution of 0.1 nm. In contrast, using a higher resolution (0.05 nm), the FP mode cannot be clearly resolved in a CMD-type QD laser according to an exemplary embodiment of the invention (see inset of FIG. 15b), which corresponds to a theoretical separation of longitudinal mode at 0.28 nm for L=800 μm. This evidences that these longitudinal modes merge physically to construct the broad spectrum emission.

The BLD spectra with varying injection levels are depicted in FIG. 15A and the corresponding full-width at half-maximum (FWHM) and spectrum ripple as a function of injection level is shown in FIG. 15B from both as-cleaved facets of a CMD-type QD laser having a cavity length L=800 μm.

Laser characteristics of a device according to an exemplary embodiment of the invention are described in the following paragraph. The deduced transparent threshold current density at infinite length Jₜᵣ (e.g., deduced from a plot of Jₜᵣ verses 1/L) is 420 A/cm² or about 82 A/cm² per QD layer from the relationship between Jₜₕ and the inverse of cavity length L. The internal quantum efficiency ηᵢₙₜ and optical loss αᵢ can be extracted from the slope of the dependence of the external quantum efficiency ηₑₓₜ on the cavity length to be ηᵢₙₜ=91% and αᵢ=4.5 cm⁻¹, respectively. The oscillations of Fabry-Perot (FP) modes overlap to produce a broad wavelength emission with a nearly flat top profile from supermodes of FP oscillations present in the laser cavity. As the injection level is increased to 2×Iₜₕ, the spectrum broadens towards a shorter wavelength and gives a FWHM of 21 nm.

The inset of FIG. 15b depicts the broadband emission in the linear scale taken with a spectrum resolution of 0.05 nm. The observation is in contrast with the general characteristics of typical semiconductor lasers based on interband transition. A slight decrease in the lasing linewidth of ˜2 nm is observed at high current injection due to the GS gain saturation at the injection above 2×Iₜₕ. This result implies that the broadband emission of the device can be maintained over a large current injection range from over 2×Iₜₕ. The relatively flat-topped lasing spectra is maintained with a corresponding side mode suppression ratio (SMSR) of >25 dB and a ripple of less than 3 dB when driven above 2×Iₜₕ.

The invention is described above with reference to QDs, which are referred to above as quantum dots and/or quantum dashes. The term QD as used herein generally encompasses quantum nano heterostructures. Such quantum nano heterostructures may be quantum wells, quantum dots, quantum dashes, quantum wires, or combinations of the foregoing.

Although the invention is illustrated and described herein with reference to specific embodiments, the invention is not intended to be limited to the details shown. Rather, various modifications may be made in the details within the scope and range of equivalents of the claims and without departing from the invention. The foregoing describes the invention in terms of embodiments foreseen by the inventors for which an enabling description was available, although insubstantial modifications of the invention, not presently foreseen may nonetheless represent equivalents thereto.

What is claimed is:

1. A broadband laser comprising:
a first cladding layer;
a second cladding layer; and
a semiconductor structure between the first and second cladding layers, having a layer of inhomogeneous quantum nano heterostructures engineered to lase at a ground state and at an excited state.

2. The laser of claim 1 wherein the layer of inhomogeneous quantum nano heterostructures is engineered to simultaneously lase at a ground state and a plurality of excited states.

3. The laser of claim 1 comprising quantum barriers sandwiching the layer of quantum nano heterostructures.

4. The laser of claim 1 wherein the quantum nano heterostructures are quantum wells, quantum dots, quantum dashes, quantum wires, or combinations thereof.

5. The laser of claim 1 comprising a plurality of layers of inhomogeneous quantum nano heterostructures.

6. The laser of claim 5 wherein each of the plurality of layers has quantum nano heterostructures that differ from those of other of the plurality of layers in at least one of size, material composition, and geometry.

7. The laser of claim 1 wherein the layer of inhomogeneous quantum nano heterostructures comprises at least one of quantum dots, quantum dashes, and quantum wires, embedded in a quantum well layer.

8. The laser of claim 1 wherein spacing between quantized states of the quantum nano heterostructures is equal to or greater than approximately 10 meV.

9. The laser of claim 1 wherein variation of sizes of the quantum nano heterostructures in the layer of the quantum nano heterostructures is greater than 10%.

10. The laser of claim 1 wherein variation of band gap energies of the quantum nano heterostructures in the layer of the quantum nano heterostructures is greater than 8 meV.

11. The laser of claim 1 having an output spectrum wavelength span of at least 10 nm with less than 5 dB of spectrum modulation.

12. The laser of claim 1 wherein the laser is a Fabry Perot broadband laser.

13. The laser of claim 1 wherein the quantum nano heterostructures are engineered to have one of multiple bandgaps and graded bandgaps using one of quantum well, dot and dash intermixing.

14. The laser of claim 1 wherein the semiconductor structure has a first portion with a first cavity length and a second portion with a second cavity length, the laser comprising first and second electrodes for independently controlling output of the first and second portions.

15. The laser of claim 14 wherein a bandgap of at least one of the cavities is engineered using quantum intermixing.

16. A photonic device comprising a semiconductor structure having a layer of inhomogeneous quantum nano heterostructures engineered to lase at least at a ground state and at an excited state.

17. The photonic device of claim 16 wherein the semiconductor quantum nano heterostructures are formed on a substrate and the device comprises a resonator formed on the substrate.

18. The photonic device of claim 16 wherein the semiconductor structure is formed on a substrate and the device comprises an optical isolator formed on the substrate for integrating the photonic device and an optical device.

19. The photonic device of claim 18 wherein the optical device comprises at least one of a tunable filter, a wavelength multiplexer, and a wavelength demultiplexer.

20. The photonic device according to claim 16 comprising a multiplexing or demultiplexing device for tuning a wavelength of an output of the photonic device.

21. The photonic device according to claim 16 comprising a tunable filter for receiving a broadband output from the semiconductor structure and generating a filtered output having a bandwidth less than the bandwidth of the broadband output.

22. An optical coherent tomography system comprising a photonic device according to claim 16 for generating light, a wavelength splitter for directing the light to a sample, and a photodetector for detecting an image from the sample.

23. The photonic device according to claim 16 comprising a plurality of semiconductor structures formed on a single substrate, each of the plurality of semiconductor structures having a layer of inhomogeneous quantum dots engineered to lase at a ground state and at an excited state.

24. The photonic device according to claim 23 wherein each of the plurality of semiconductor structures generates light at a different center wavelength.

25. A method of forming a broadband laser comprising:
forming a first cladding layer on a substrate;
forming an active region on the first cladding layer, the active region having a plurality of inhomogeneous quantum nano heterostructures engineered to lase at a ground state and at an excited state;
forming a second cladding layer on the active layer.

26. The method according to claim 25 wherein the active region is formed by an iterative growth process, with at least one iteration having a slightly dissimilar quantum energy transition from other iterations.

27. The method according to claim 25 wherein the active region is formed by performing quantum intermixing.

28. The method according to claim 25 wherein the quantum nano heterostructures are formed using at least one of a Stranski-Krastanow process and a cycle monolayer deposition process in one of a molecular beam epitaxy and a metal organic vapor pressure deposition system.
